(19) United States
(12) Patent Application Publication
(10) Pub. No.: US 2012/0077327 A1
(43) Pub. Date: Mar. 29, 2012

(54) Formation of a Shallow Trench Isolation Structure

(75) Inventors: Nicolas Degors, Jean Monnet (FR); Erwan Dornel, Jean Monnet (FR)

(73) Assignee: International Business Machines Corporation, Armonk, NY (US)

(21) Appl. No.: 13/236,815

(22) Filed: Sep. 20, 2011

(30) Foreign Application Priority Data
Sep. 29, 2010 (EP) 10306053.9

(51) Int. Cl. H01L 21/762

(52) U.S. Cl. 438/424; 257/E21.546

(57) ABSTRACT

A method of forming a shallow trench isolation structure such that the shoulders of the wall formations on either side of the trench are rounded, whilst the walls and floor of the trench as well as the top surface of the formations on either side of the trench remain flat. This is achieved by anchoring the walls and floors with a partial gap fill, which may be achieved either by fully filling the gap and then reducing the level to below that of the formations on either side a the trench by polishing and etching steps, or by not completely filling the trench in the first place. The tops of the formations on either side of the trench meanwhile are protected by an oxide layer, which is pared back from the edge of the trench, for example by means of an isotropic etching process.

### FIELD OF THE INVENTION

The present invention relates to the fabrication of integrated circuits and pertains particularly to the fabrication of Shallow Trench Isolation (STI) structures.

### BACKGROUND OF THE INVENTION

STI technology has various advantages over the former isolation process called LOCOS for ‘local oxidation of silicon’. For example, STI allows for the planarization of the isolation structure. This results in better control of the critical dimension when defining the gate stack of a transistor. STI is now is the most common way to isolate semiconductor devices.

FIG. 1 shows exemplary device cross sections at different stages of a typical STI process.

FIG. 2 is a flowchart of the steps of the prior art process of FIG. 1.

At a first step 202 a buffer oxide layer (called ‘padox’) 120 of 5 to 20 nanometers (nm) is thermally grown on wafer substrate 110 to arrive at the structure shown in FIG. 1a.

As shown in FIG. 1b a nitride (SiN) layer 130 of approximately 200 nm is next deposited over the oxide layer 120 at a step 204.

As shown in FIG. 1c the Nitride layer 130 is patterned with lithography to form nitride walls 131, 132 at a step 206.

As shown in FIG. 1d the oxide layer 121 is etched down to the semiconductor substrate 110 at a step 208 where it is left exposed by the patterning step 206.

As shown in FIG. 1e an etch that is selective to the semiconductor substrate material is then used at step 210 to etch a trench 111 into the semiconductor substrate where it is left exposed by the etching of the oxide layer.

As shown in FIG. 1f a liner oxide 140 is thermally grown at step 212 on the walls of the trench 111 to anneal out any damage to the semiconductor and passivate the semiconductor substrate 110.

As shown in FIG. 1g, a dielectric material such as an oxide 150 that is considerably thicker than the trench depth is deposited at step 214. This is commonly called the ‘gap fill’ step.

As shown in FIG. 1h the wafer is then subjected at step 216 to a chemical-mechanical polishing (CMP) step 216 that stops when it reaches the upper surface of the nitride layer 131, 132, to leave oxide 151 in the gap 111 alone.

As shown in FIG. 1i The nitride layer 131, 132 is then stripped at step 224, along with buffer oxide 121, 122 underneath at step 226, thereby forming the final STI structure.

As shown in FIG. 1i, the process of FIG. 1 produces a sharp corner 112 where the trench side wall meets the semiconductor surface. This sharp corner 112 is the cause of many problems with device performance, yield, and reliability.

FIGS. 3 and 4 show TCAD simulations of the electric field at the corner 112 with different levels of rounding in a working MOSFET. The cross sections reveal absolute electric field for a voltage drop of 15V between the active material and the gate of the MOSFET for high and low curvature of the active material. The gate oxide thickness is 150 angstroms for both MOSFETs FIG. 3 shows a cross section of a first MOSFET showing the gate 360, Gate oxide 370 and active material 311 in a first configuration with a sharp corner 312. FIG. 4 meanwhile shows a cross section of a second MOSFET showing the gate 360, Gate oxide 370 and active material 311 in a second configuration with a rounded corner 312. In both FIGS. 3 and 4 the electric field intensity is indicated by the shading of the various parts of the MOSFET, and it is clear that the Electric Field is strongly concentrated around the sharp corner 312 of FIG. 3, reaching levels of 1.3×10⁻⁷ V/cm over a large area whilst being generally weaker around the rounded corner 312 of FIG. 4, in which the Electric Field levels are considerably better controlled. This high field concentration which will tend to create artifacts such as variation in the threshold voltage of the MOSFET, and a higher current leakage through the oxide.

The effect of the corner can be explained by a different gate control at the corner: this corner effect issue is well known in FinFETs or multi-gate MOSFETs.

In view of this effect, it is considered desirable to provide a rounded top corner of the trench in order to achieve stable device performance (no kink on the subthreshold of the drain current versus gate voltage characteristic) and maintain good gate oxide integrity.

There exist a number of prior art techniques for achieving such a configuration.

A first group of techniques to minimize corner effect involves an additional implant. The general idea of this group of techniques is to add an implant in order to obtain a non constant implantation dose along the width of the channel of the MOSFET. U.S. Pat. No. 6,521,493B1, U.S. Pat. No. 5,994,202 and U.S. Pat. No. 6,084,276 are examples of this general approach. Drawbacks of this group of techniques: This technique does not directly solve the corner effect problem, hit rather seeks to minimise its negative effects. The corner effect is not fully minimised in particular because the protruding sidewalls of STI are still effective (the radius of curvature at the STI edge is still low).

A second group of techniques to minimize corner effect involves wet or dry oxidation of/during the liner formation step (as describe above with reference to FIG. 1f. The liner oxidation is designed by selection of proper temperature, time, ambient, and pre-clean factors so as to get high oxidation thickness at the corner to get high radius of curvature.

U.S. Pat. No. 6,150,234, U.S. Pat. No. 5,811,346, U.S. Pat. No. 6,326,283 B1, U.S. Pat. No. 6,406,977B2, Nandakumar et al., shallow trench isolation for advanced VLSI CMOS technologies, IEDM technical digest, pp. 133-136, 1998, are examples of this general approach. A key draw back of this group of techniques is low control of the radius of curvature leading to low control of the threshold voltage of the MOS.

A third group of techniques to minimize corner effect comprises creating a ‘bird-beak’ at the STI corner by re-oxidation of the padox when the STI is already filled.

FIG. 5 shows an STI device with a bird-beak formation. As shown in FIG. 5 there is provided an STI device comprising a substrate 510, oxide layer 521, gap fill 551 and nitride layer 531 substantially as described with respect to FIG. 1. As shown however a portion of the oxide layer 521 is exposed between the edge of the nitride layer 531 and the top of the gap fill 551. When this exposed portion is subjected to a further oxidation process, it swells to form the bird-beak structure 525 as shown, thus achieving a rounded shape. The U.S. Pat. No. 5,989,978 is example of this approach. Drawbacks of this group of techniques include a low control of the radius of curvature leading to low control of the threshold voltage of the MOS.

A fourth group of techniques to minimize the corner effect involves the fabrication of spacer at the STI side, as described in U.S. Pat. No. 6,750,117B1. The main drawback of this approach in the substantial increase in process complexity necessary, meaning that this is a costly solution.

A fifth group of techniques to minimize the corner effect involves sputter etching the edges of the trench so as to rounds the corner of the trench, as described in U.S. Pat. No. 6,228,727B1. A significant drawback of this group of techniques is the associated increase the number of defects. Due to the sputter etching process.

A sixth group of techniques to minimize corner effect involves thermal annealing causing the surface of the active material to flow. Examples of these include. U.S. Pat. No. 6,746,933B1, U.S. Pat. No. 6,746,936B1, U.S. Pat. No. 6,670,279B1,U.S. Pat. No. 6,825,087B1, Shimizu 2006 [Shi06], Matsuda 1998 [Mat98]

### SUMMARY OF THE INVENTION

According to the present invention there is provided a method of forming an isolation structure on an integrated circuit according to the appended independent claim 1, a computer program according to the appended claim 14 and a computer readable according to the appended claim 15. Preferred embodiments are defined in the appended dependent claims.

Further advantages of the present invention will become clear to the skilled person upon examination of the drawings and detailed description. It is intended that any additional advantages be incorporated herein.

### BRIEF DESCRIPTION OF THE DRAWINGS

Embodiments of the present invention will now be described by way of example with reference to the accompanying drawings in which like references denote similar elements, and in which:

FIG. 1 shows exemplary device cross sections at different stages of a typical STI process;

FIG. 2 is a flowchart of the steps of the prior art process of FIG. 1;

FIG. 3 shows a cross section of a first MOSFET with a sharp corner;

FIG. 4 shows a cross section of a second MOSFET with a rounded corner;

FIG. 5 shows an STI device with a bird-beak formation;

FIG. 6 shows the possible results of annealing with an unanchored gap floor; and more particularly

FIG. 6a shows an STI structure with an unanchored gap floor, before annealing;

FIG. 6b shows an STI structure with an unanchored gap floor after annealing;

FIG. 7 shows the possible results of annealing where the active region has an unanchored top surface; and more particularly

FIG. 7a shows an STI structure where the active region has an unanchored top, before annealing;

FIG. 7h shows an STI structure with where the active region has an unanchored top after annealing;

FIG. 8 shows the steps of method according to a first embodiment;

FIG. 9a shows the configuration of the STI structure after step 216;

FIG. 9b shows the configuration of the STI structure after step 818;

FIG. 9c shows the configuration of the STI structure after step 820;

FIG. 10 shows the steps of method according to a second embodiment;

FIG. 11a shows the configuration of the STI structure after step 216;

FIG. 11b shows the configuration of the STI structure after step 1017;

FIG. 11c shows the configuration of the STI structure after step 1018;

FIG. 11d shows the configuration of the STI structure after step 1020;

FIG. 12 shows the steps of method according to a third embodiment;

FIG. 13a shows the configuration of the STI structure after step 212;

FIG. 13b shows the configuration of the STI structure after step 1213;

FIG. 13c shows the configuration of the STI structure after step 1218;

FIG. 13d shows the configuration of the STI structure after step 1220;

FIG. 14 shows the steps of method according to a fourth embodiment;

FIG. 15a shows the configuration of the STI structure after step 212;

FIG. 15b shows the configuration of the STI structure after step 1214;

FIG. 15c shows the configuration of the STI structure after step 1418;

FIG. 15d shows the configuration of the STI structure after step 1420; and

FIG. 16 shows in greater detail the results of the migration step.

### DETAILED DESCRIPTION

There are disclosed herein further improvements to techniques using thermal annealing as described above. In particular, in studying the results of the available prior art it has been determined that the annealing of the structures described in these documents leads to sub optimal formations, in particular due to the fact that they allow parts of the device to flow under the annealing process that should ideally retain their original configuration, whilst the annealing should be limited to the corner region as described above. In particular, it may be determined that in the approach of U.S. Pat. No. 6,746,933B1 the top of the active region will be subject to undesirable flow during annealing, in U.S. Pat. No. 6,746,936B1. U.S. Pat. No. 6,670,279B1 and Matsuda 1998 the floor of the gap will be subject to undesirable flow during annealing, and in U.S. Pat. No. 6,825,087B1 and Shimizu 2006 both the top of the active region and the floor of the gap will be subject to undesirable flow during annealing. In other words, at least one of the surfaces (either the bottom of the STI or the top of the active material) is a free surface.

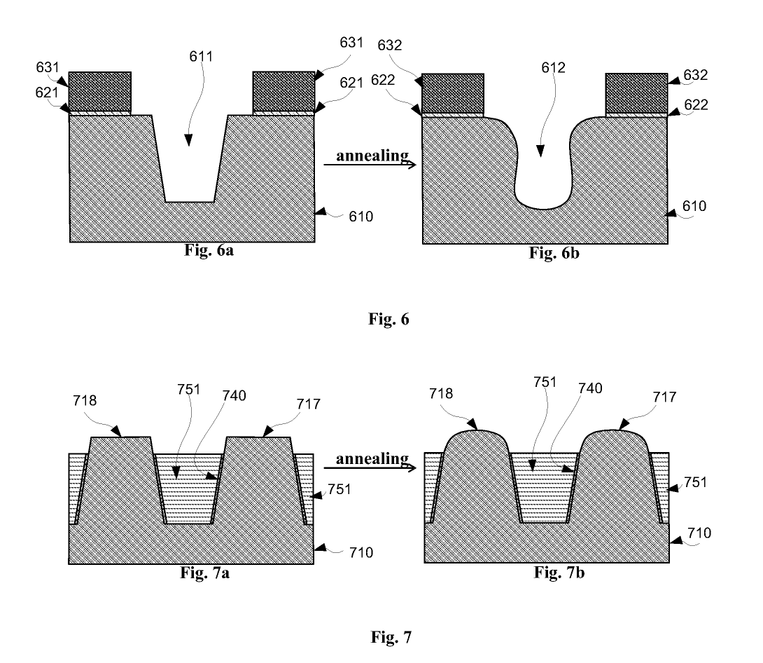

FIG. 6 shows the possible results of annealing with an unanchored gap floor.

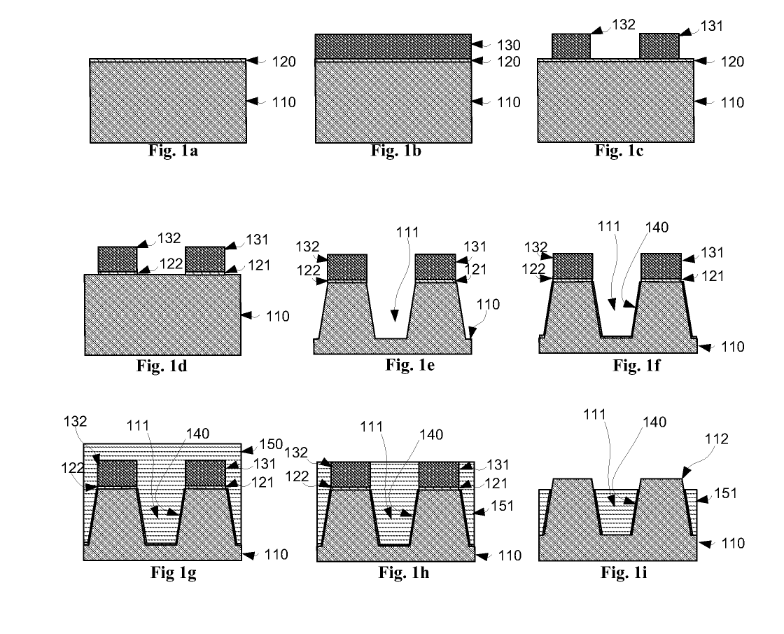

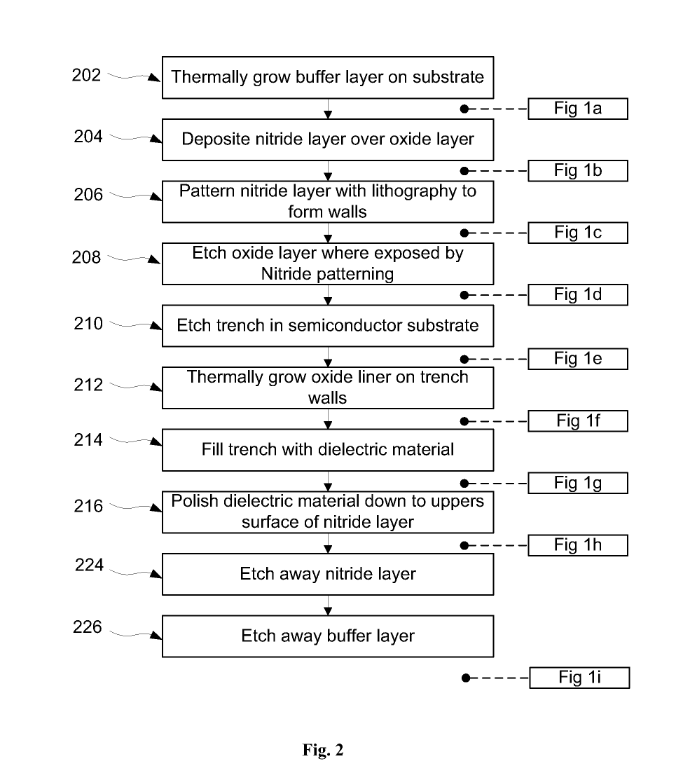

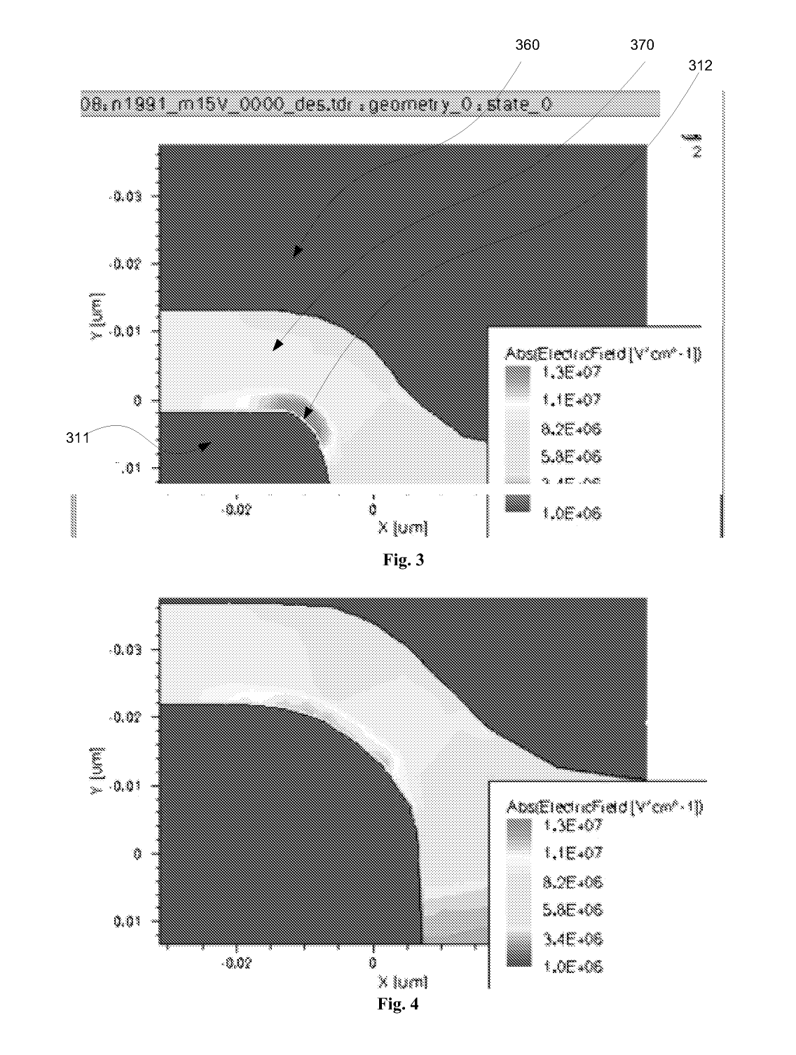

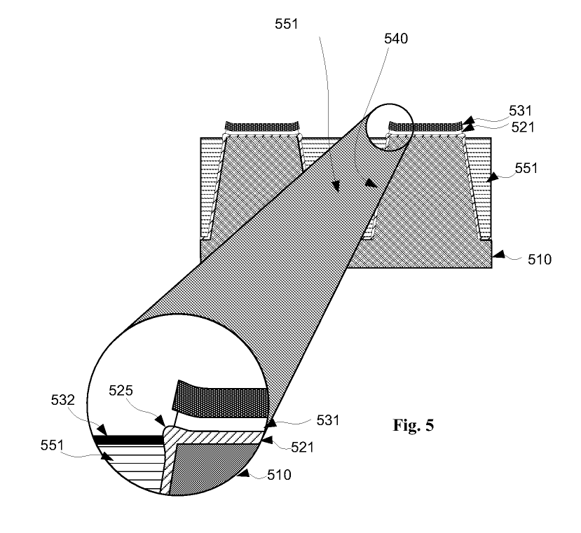

FIG. 6a shows an STI structure with an unanchored gap floor, before annealing. In particular there is provided an STI structure substantially as shown in FIG. 1e, comprising Nitride layers 631 and 632, oxide layers 621 and 622 and substrate 610 incorporating gap 611.

FIG. 6b shows an STI structure with an unanchored gap floor after annealing. In particular as shown the Nitride layers 631 and 632, oxide layers 621 and 622 and substrate 610 incorporating gap 611 of FIG. 6a are all present, however the form of the gap 611 has been substantially modified to form modified gap 612, with all of its exposed surfaces, which were comprised of planar surfaces in FIG. 6a, now softened into a continuous curve, and with the lips of the modified gap 612 overhanging the floor of the gap and the floor itself being concave.

FIG. 7 shows the possible results of annealing where the active region has an unanchored top surface.

FIG. 7a shows an STI structure where the active region has an unanchored top, before annealing. In particular there is provided an STI structure substantially as shown in FIG. 1i, comprising substrate 710, lined with a liner layer 740 and filled with a dielectric 751 and 752. On either side of the gap 751 and 752 the top surface of the substrate 710 defines flat surfaces 717 and 718, standing above the upper limit of the gap 751 and each defining an exposed corner with a respective wall of the gap as described above.

FIG. 7b shows an STI structure with where the active region has an unanchored top after annealing. In particular as shown the substrate 710, lined with a liner layer 740 and filled with a dielectric 751 and 752 of FIG. 6a are all present, however the corner has been rounded, and the surfaces 717 and 718 have merged into continuous curves with the corner and the exposed part of the gap walls.

In consequence, in neither of the configurations of FIGS. 6 and 7 is an equilibrium state achieved, and the active material continues to diffuse by capillary action. In consequence, this tends to compromise the planarity and/or the gapfill process. This is also a drawback in the definition of the anneal: if the anneal is too long or too high in temperature, the active material continues to flow, but on the other hand if the anneal is too short or too low in temperature, The corner of the active material will not be rounded. This in turn leads to difficulties in selecting the optimum process conditions of the anneal in terms of temperature, time, pressure and nature of the gas.

Embodiments of the present invention accordingly seek to reduce such corner effect problems by exposed only the corner of the active material. Then an annealing is done so that only the free surface (i.e. not covered) flows.

Advantages of the proposed approach include the fact that it makes the corner of the active material rounded without disturbing the rest of the active material (namely the top of the active material and the bottom of the STI. A further advantage is that, once only the corner of the active material is exposed, the process conditions of the annealing become less critical. Indeed, the equilibrium state after annealing, corresponding to an active material free surface which is perfectly rounded i.e. mathematically with a constant radius of curvature along the free surface, is a desirable or at least acceptable geometry wanted.

Generally speaking, there is provided a method of forming an isolation structure on an integrated circuit, said method comprising the steps of: forming an at least partially filled trench trench structure on a substrate, wherein only the top corner of the surface of the substrate forming the trench structure is exposed, and migrating the exposed part of the surface of the surface of the substrate forming the trench structure. The migration of the exposed part of the surface of the active material preferably comprises annealing the part of said substrate exposed between the upper limit of said dielectric material and the end of said recess.

According to certain embodiments, the method may comprise the further step of filling the trench with dielectric material, and performing a selective etch so as to remove an upper part of said dielectric material, leaving said trench partially filled to below its lip with said dielectric material. This approach is described in more detail below with respect the first, second and third embodiments.

According to certain embodiments, the step of forming a trench may comprises using a mask layer selective to the trench etch and disposing an oxidation layer on either side of said trench, and partially filling said trench to below its lip with a dielectric material. This approach is described in more detail below with respect the fourth embodiment.

According to certain embodiments, the method may comprise the further step of performing a selective etch of the buffer layer so as to form a recess between said mask layer and said substrate. This approach is described in more detail below with respect the first and second embodiments.

According to certain embodiments, there may be provided a step of chemical mechanical polishing said dielectric material down to the top of the mask layer, and then performing an anisotropic selective etch to remove at least a thickness of the dielectric equivalent to the thickness of the mask layer. This approach is described in more detail below with respect the first and second embodiments.

According to certain embodiments, there may be provided a step of etching said nitride layer so as to recess said nitride layer from the edge of said trench. This approach is described in more detail below with respect the third embodiment.

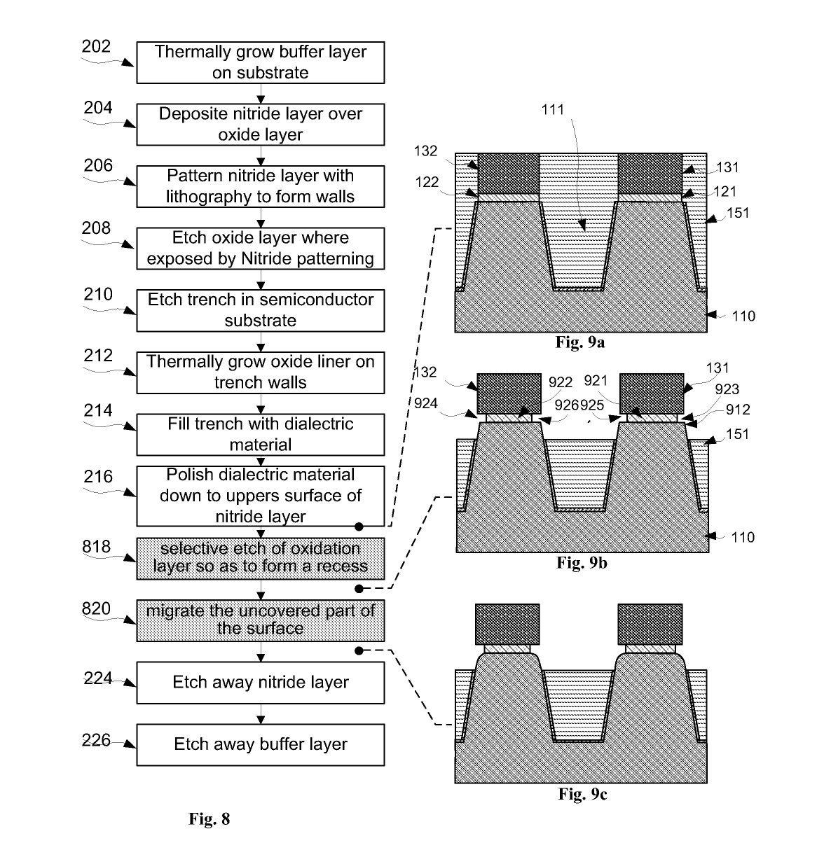

FIG. 8 shows the steps of method according to a first embodiment. According to the First embodiment, steps 202 to 216 are implemented as described above with reference to FIG. 2.

While for the purposes of the following discussions the process steps of FIGS. 1 and 2 will generally be followed so as to put the invention in context, it will be appreciated that many alternative processes are equally applicable, for example as regards the formation of the trench.

The various numerical parameters specified in the discussion of FIGS. 1 and 2 are subject to variation in view of the specification to be achieved. In particular the Nitride layer may be substantially thinner than that described above, for example in the order of 80 nm.

FIG. 9a shows the configuration of the STI structure after step 216. FIG. 9a is as such identical to FIG. 1h.

In accordance with the first embodiment, the method next proceeds to step 818 at which a selective etch is performed so as to form a recess in the buffer layer 121, 122, between the mask layer 131, 132 and the substrate 110. The selective etch may advantageously be an isotropic etch, using an appropriate etchant.

The etchant may be a corrosive liquid or a chemically active ionized gas, or plasma. The etchant will be chosen as a function of the formulation of the buffer layer 121, 122 and the dielectric material 151 filling the gap. Where these the buffer layer 121, 122 and the gap fill 151 are of silicon dioxide, a buffered hydrofluoric acid would be a common choice of etchant for isotropic wet etching. By this means, not only is a recess formed between the mask layer 131, 132 and the substrate 110, but the same etching process will etch away the upper part of the gap fill, so as to expose the corner of the active layer 110.

FIG. 9b shows the configuration of the STI structure after step 818. As shown, recesses 923, 924, 925, 926 have been created by etching away a part of the buffer layers 921, 922. By the same process the level of the gap fill 151 has been reduced, exposing corners 912 etc.

The method now proceeds to step 820 of migrating the exposed part of the substrate 110. Specifically, the only parts of the substrate 110 that are exposed are the corners 912 exposed by step 818.

The migration of step 818 preferably comprises an annealing process, and still more preferably hydrogen anneal.

By way of example, this anneal may advantageously be performed under H2 pressure at a temperature between 600° C. and 1000° (with an optimum at 900° C.). The anneal may advantageously be performed at a pressure between 0.1 Torr and ambient pressure with an optimum at 20 Torr.). The anneal may advantageously be performed for a period of between 15 seconds and 30 minutes.

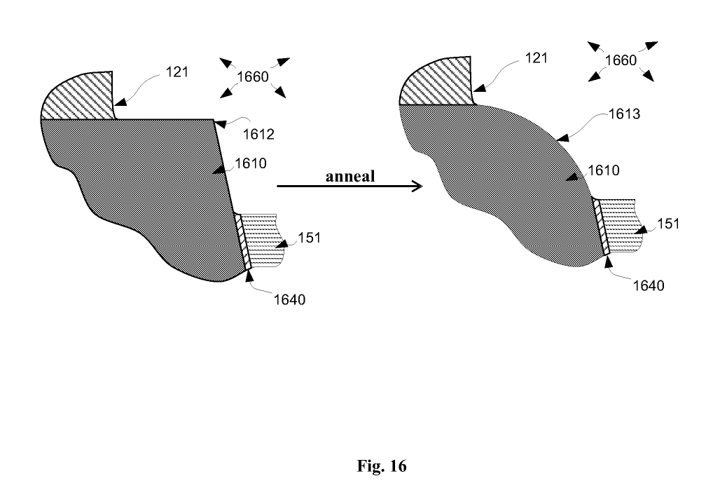

These conditions will tend to cause the Silicon free surface to flow so as to minimize the surface energy. During the thermal annealing, the active material tends to flow until equilibrium state, i.e. the shape of the free surface of the active material tends to be modified. The resulting form is discussed in more detail with reference to FIG. 16 below.

FIG. 9c shows the configuration of the STI structure after step 820. As shown, the exposed corners 912 etc. have been rounded, whilst the top region of the active material 110 covered by the buffer layer 921, 922 and the gap fill 151 remain in their original configuration.

The conventional process as described with reference to FIGS. 1 and 2 may then resume from step 209.

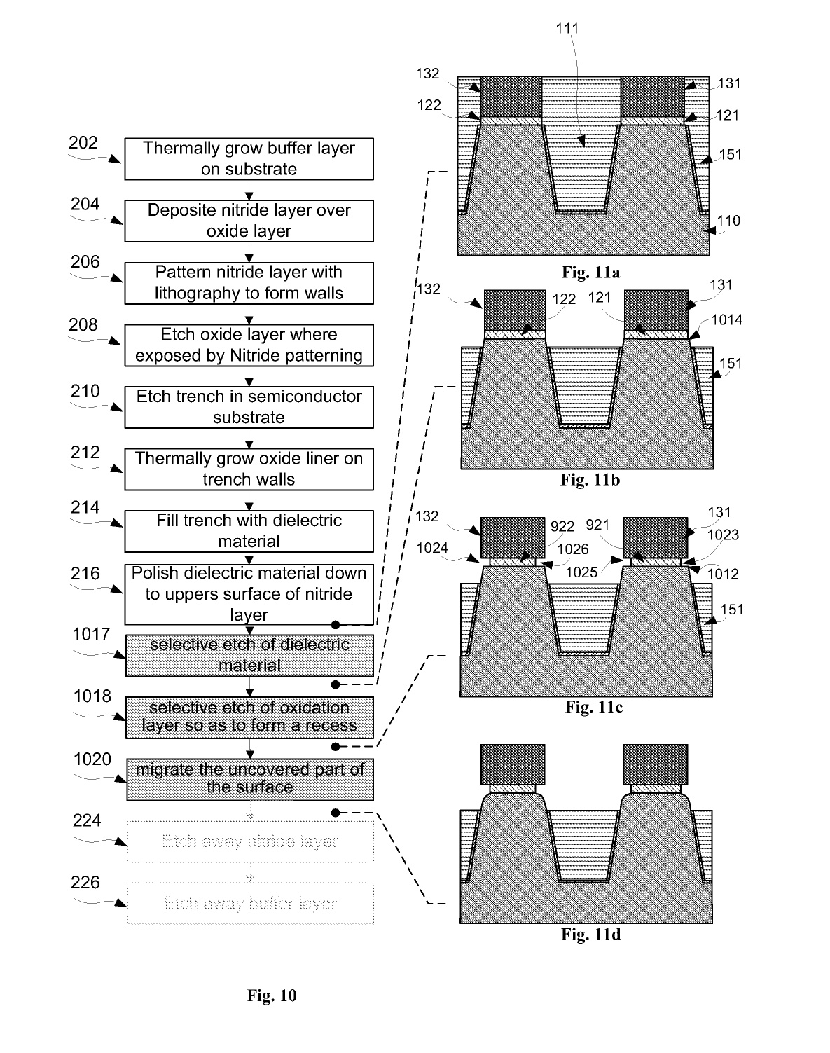

FIG. 10 shows the steps of method according to a second embodiment. According to the second embodiment, steps 202 to 216 are implemented as described above with reference to FIG. 2.

FIG. 11a shows the configuration of the STI structure after step 216. FIG. 11a is as such identical to FIG. 1h.

In accordance with the second embodiment, the method next proceeds to step 1017 at which a selective etch is performed so as to remove upper parts of the substrate 110, thereby exposing, the upper edge of the substrate 110. The selective etch may advantageously be an anisotropic etch, using for example CH₂F₂, or CH₃F, or other appropriate reagents as an etchant.

FIG. 11b shows the configuration of the STI structure after step 1017. As shown, the level of the gap fill 151 has been reduced, exposing upper edges 1014 etc. of the substrate 110.

The method next proceeds to step 1018 at which a selective etch is performed so as to form a recess in the buffer layer 121, 122, between the mask layer 131, 132 and the substrate 110. The selective etch may advantageously be a isotropic etch, using an appropriate etchant.

The etch process of step 1018 may advantageously be performed using the same reagents and under the same conditions as set out for equivalent step 818 above.

FIG. 11c shows the configuration of the STI structure after step 1018. As shown, recesses 1023, 1024, 1025, 1026 have been created by etching away a part of the buffer layers 121, 122, exposing corners 1012 etc.

The method now proceeds to step 1020 of migrating the unconvered part of the substrate 110. Specifically, the only parts of the substrate 110 that are exposed are the corners 1012 exposed by step 1018.

The migration of step 1220 preferably comprises an annealing process, which may advantageously be performed under the same conditions as set out for equivalent step 820 above.

FIG. 11d shows the configuration of the STI structure after step 1020. As shown, the exposed corners 1012 etc. have been rounded, whilst the top region of the active material 110 covered by the buffer layer 921, 922 and the gap fill 151 remain in their original configuration.

The conventional process as described with reference to FIGS. 1 and 2 may then resume from step 224.

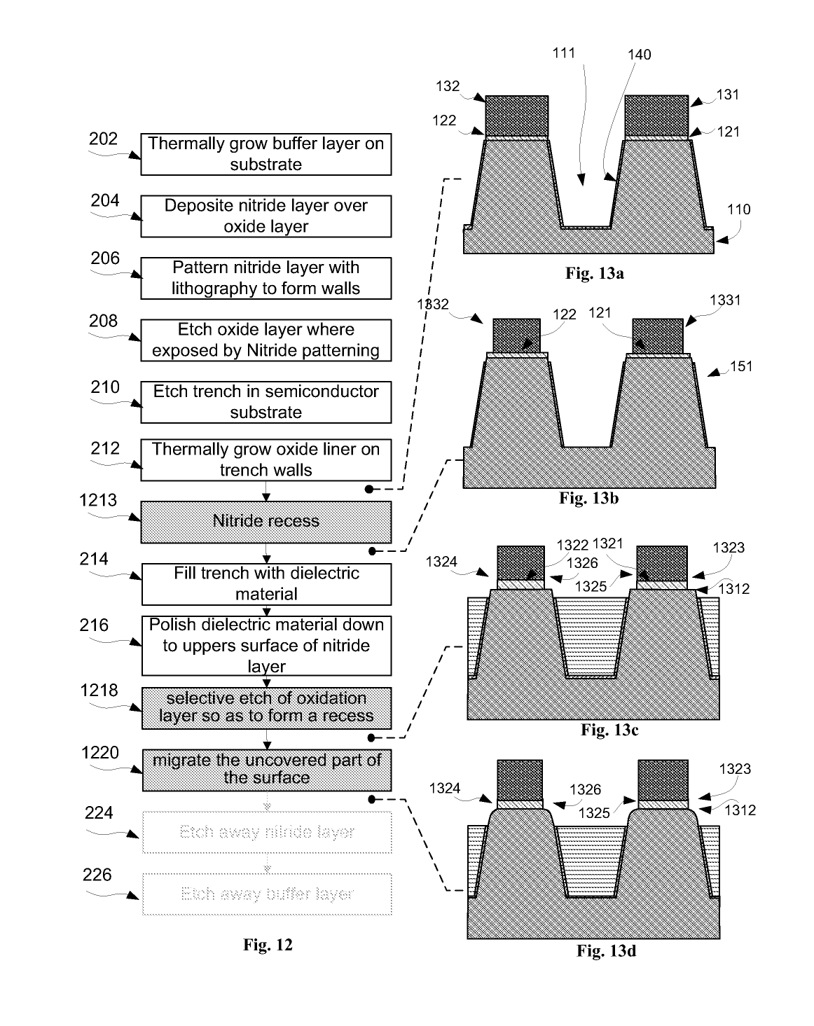

FIG. 12 shows the steps of method according to a third embodiment. According to the third embodiment, steps 202 to 212 are implemented as described above with reference to FIG. 2.

FIG. 13a shows the configuration of the STI structure after step 212. FIG. 13a is as such identical to FIG. 1f.

In accordance with the third embodiment, the method next proceeds to step 1213. At step 1213 a nitride recess process is carried out, reducing the width of the nitride mask layer 131, 132 so as to leave exposed the edge portions of the underlying barrier layer 121, 122

FIG. 13b shows the configuration of the STI structure after step 1213. As shown, the structure is substantially the same as that of FIG. 13h, with the exception that mask layers 1331 and 1332 are narrower than the underlying buffer layers 121, 122, as a result of the nitride recess of step 1213.

In accordance with the third embodiment, the method next proceeds to steps 214 and 216 which are carried out substantially as described with respect to FIGS. 1 and 2. The method then proceeds to step 1218 at which a selective etch is performed so as to remove the part of the buffer layers 121, 122 exposed by the step 1213.

The etch process of step 1218 may advantageously be performed using the same reagents and under the same conditions as set out for equivalent step 1017 above.

FIG. 13c shows the configuration of the STI structure after step 1218. As shown, recesses 1323, 1324, 1325, 1326 have been created by etching away a part of the buffer layers 121, 122. By the same process the level of the gap fill 151 has been reduced, exposing corners 1312 etc.

The method now proceeds to step 1220 of migrating the unconvered part of the substrate 110. Specifically, the only parts of the substrate 110 that are exposed are the corners 1312 exposed by step 1218.

The migration of step 1220 preferably comprises an annealing process, which may advantageously be performed under the same conditions as set out for equivalent step 820 above.

FIG. 13d shows the configuration of the STI structure after step 1220. As shown, the exposed corners 1312 etc. have been rounded, whilst the top region of the active material 110 covered by the buffer layer 1321, 1322 and the gap fill 151 remain in their original configuration.

The conventional process as described with reference to FIGS. 1 and 2 may then resume from step 224

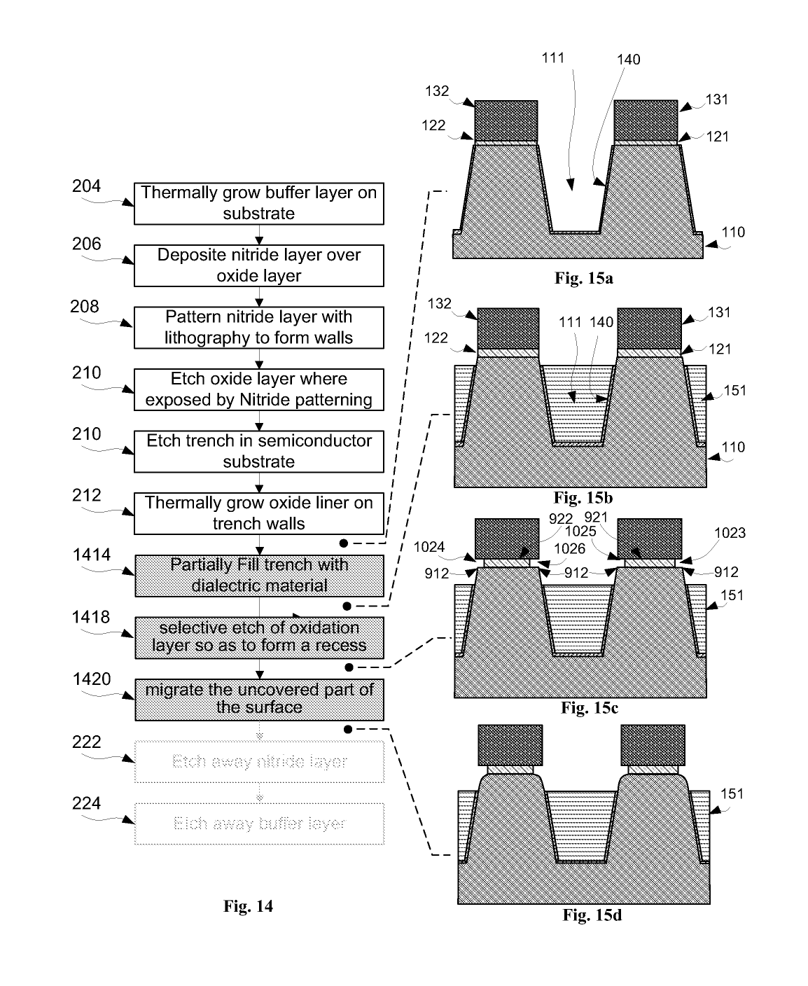

FIG. 14 shows the steps of method according to a fourth embodiment. According to the fourth embodiment, steps 202 to 212 are implemented as described above with reference to FIG. 2.

FIG. 15a shows the configuration of the STI structure after step 212. FIG. 15a is as such identical to FIG. 1f.

In accordance with the fourth embodiment, the method next proceeds to step 1414. At step 1414 the trench 111 is partially filled with a dielectric material, leaving exposed the upper edges of the walls of the underlying substrate 110.

FIG. 15b shows the configuration of the STI structure after step 1414. As shown, the structure is substantially the same as that of FIG. 15a, with the exception that the trench 111 is partially filled with a dielectric material 151, leaving exposed the upper edges of the walls of the underlying substrate 110.

In accordance with the Fourth embodiment, the method next proceeds to step 1418 at which a selective etch is performed so as to form a recess in the buffer layer 121, 122, between the mask layer 131, 132 and the substrate 110. The selective etch may advantageously be a isotropic etch, using an appropriate etchant.

The etchant may be a corrosive liquid or a chemically active ionized gas, or plasma. The etchant will be chosen as a function of the formulation of the buffer layer 121, 122 and the dielectric material 151 filling the gap. Where these the buffer layer 121, 122 and is of silicon dioxide, a buffered hydrofluoric acid would be a common choice of etchant for isotropic wet etching. By this means, a recess formed between the mask layer 131, 132 and the substrate 110. Since the level of the gap fill was reduced in the preceding step 1017, it may not be necessary, and in some cases it may not be desirable to further reduce the level of the gap fill at step 1418. Where this is the case the etchant may be chosen to be selective to the material of the buffer layer. In any case, this step exposes the corner of the active layer 110.

FIG. 15c shows the configuration of the STI structure after step 1418. As shown, recesses 1023, 1024, 1025, 1026 have been created by etching away a part of the buffer layers 121, 122, exposing corners 912 etc.

The method now proceeds to step 1420 of migrating the exposed part of the substrate 110. Specifically, the only parts of the substrate 110 that are exposed are the corners 912 exposed by step 1418.

The migration of step 1420 preferably comprises an annealing process, which may advantageously be performed under the same conditions as set out for equivalent step 820 above.

FIG. 15d shows the configuration of the STI structure after step 1420. As shown, the exposed corners 912 etc. have been rounded, whilst the top region of the active material 110 covered by the buffer layer 921, 922 and the gap fill 151 remain in their original configuration.

The conventional process as described with reference to FIGS. 1 and 2 may then resume from step 222.

The equilibrium state obtained via the migration step as described in the forgoing embodiments is the one which minimizes the surface energy, in accordance with Wulff's theorem. Assuming an isotropic surface energy, this geometry corresponds mathematically to a surface with a constant radius of curvature, that is, a circle in 2D or in a system which present an invariance by translation, or a sphere in 3D.

Assuming neither deposit/etch of active material nor reaction with other material, thus excluding no SiO desorption for example, the equilibrium state should verify a constant volume of the active material.

FIG. 16 shows in greater detail the results of the migration step.

As shown in FIG. 16 the oxidation layer 121 and the liner layer 1640 can be considered to form a meniscus, defining triple points between the active material 1610, the oxide 121, 1640 and the gas 1660, which can be considered as fixed (triple angle less than the Young angle which can be considered close to 90° for the system Si/SiO2/gas. From these three assumptions, one can calculate the shape of the equilibrium state (geometric problem). Thus as shown, the migration step will reconfigure the corner 1612 to a rounded surface 1613 exhibiting a minimum energy.

Accordingly there is provided a method of forming a shallow trench isolation structure such that the shoulders of the wall formations on either side of the trench are rounded, whilst the walls and floor of the trench as well as the top surface of the formations on either side of the trench remain flat. This is achieved by anchoring the walls and floors with a partial gap fill, which may be achieved either by fully filling the gap and then reducing the level to below that of the formations on either side a the trench by polishing and etching steps, or by not completely filling the trench in the first place. The tops of the formations on either side of the trench meanwhile are protected by an oxide layer, which is pared back from the edge of the trench, for example by means of an isotropic etching process. By these provisions the shoulders or upper corners of the formations on either side a the trench are exposed, so that a migration process such as annealing will cause these surfaces to round out so as to minimise their surface energy, whilst the walls and floor of the trench as well as the top surface of the formations on either side of the trench are anchored by the gap till and the oxide layer, and remain flat.

Although certain of the preceding embodiments relate to the case of a nitride mask above a buffer layer, it will be appreciated that the principles described herein are equally applicable to configurations in which the hardmask is composed of mono or multilayer and the compound(s) may be oxide, silicon nitride, polysilicon etc. Furthermore the gap fill material may be composed of a combination of dielectric materials.

The invention can take the form of an entirely hardware embodiment, an entirely software embodiment or an embodiment containing both hardware and software elements. In a preferred embodiment, the invention is implemented in software, which includes but is not limited to firmware, resident software, microcode, etc.

Furthermore, the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

In particular, the invention may be embodied in software adapted to control the processes of a semiconductor fabrication plant.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

1. A method of forming an isolation structure on an integrated circuit, said method comprising the steps of:
forming an at least partially filled trench structure on a substrate, wherein only the top corner of the substrate forming said trench structure is exposed, and
migrating the exposed part of the surface of the substrate forming said trench structure.

2. The method of claim 1 wherein said step of migrating comprises annealing the exposed part of said substrate.

3. The method of claim 1 wherein said step of forming a trench further comprises using a mask layer selective to the trench etch and disposing an oxidation layer on either side of said trench, and partially filling said trench to below its lip with a dielectric material.

4. The method of claim 3 wherein said mask layer is composed of a hardmask layer on top of a bufkr layer.

5. The method of any of claim 4 comprising the further step of performing a selective etch of said buffer layer so as to form a recess between said mask layer and said substrate.

6. The method of claim 5 wherein said selective etch of said buffer layer is an isotropic selective etch.

7. The method of claim 1 wherein the step filling said trench with said dielectric material, and performing a selective etch so as to remove an upper part of said dielectric material, leaving said trench partially filled to below its lip with said dielectric material.

8. The method of claim 1 wherein the step of chemical mechanical polishing said dielectric material down to the top of the mask layer, and then performing a selective etch to remove at least a thickness of the dielectric equivalent to the thickness of the mask layer.

9. The method of claim 1 wherein a further step of etching said nitride layer so as to recess said nitride layer from the edge of said trench.

10. The method of claim 2 wherein said step of annealing involves a hydrogen anneal at a temperature between 600° C. and 1000°.

11. The method of claim 2, wherein said step of annealing is performed at a pressure between 0.1 Torr and ambient pressure with an optimum at 20 Torr.

12. The method of claim 2, wherein said step of annealing is performed for a period of between 15 seconds and 30 minutes.

13. The method of claim 1, preceded by a step of masking a part of said substrate by photolithography.

14. A computer program comprising instructions for carrying out the steps of the method according to claim 1 when said computer program is executed on a computer coupled to appropriate fabrication apparatus.

15. A computer readable medium having encoded thereon a computer program according to claim 14.
